(19) United States
(12) Patent Application Publication
(10) Pub. No.: US 2023/0412142 A1
(43) Pub. Date: Dec. 21, 2023

(54) PIEZOELECTRIC LAYER ARRANGEMENTS IN ACOUSTIC WAVE DEVICES AND RELATED METHODS

(71) Applicant: Qorvo US, Inc., Greensboro, NC (US)

(72) Inventor: Patrik Rath, Munich (DE)

(21) Appl. No.: 18/252,173

(22) PCT Filed: Nov. 16, 2020
(86) PCT No.: PCT/US20/60654

§ 371 Date: May 8, 2023

(51) Int. Cl. H03H 9/02; H03H 9/64; H03H 3/08; H03H 9/145

(52) U.S. Cl. CPC H03H 9/02818; H03H 9/02574; H03H 9/6483; H03H 3/08; H03H 9/14544

(57) ABSTRACT

Acoustic wave devices, and particularly piezoelectric layer arrangements in acoustic wave devices and related methods are disclosed. Acoustic wave devices may include a piezoelectric layer on a carrier substrate. The piezoelectric layer is formed with a thickness that is varied or shaped across different portions of the carrier substrate. Different piezoelectric layer thicknesses on a common carrier substrate may be provided for different surface acoustic wave (SAW) filter structures that are formed monolithically, for different sets of resonators within a single filter structure, and for different regions within a single SAW device in one or more of the transverse direction or the propagation directions. Shaping piezoelectric layers may include selectively removing or adding portions of the piezoelectric layer. In this manner, piezoelectric layer thicknesses at different hierarchy levels within SAW devices and filters may be tailored to provide different acoustic resonator properties without requiring separately formed devices on separate substrates.

### FIELD OF THE DISCLOSURE

The present disclosure relates to acoustic wave devices, and particularly to piezoelectric layer arrangements in acoustic wave devices and related methods.

### BACKGROUND

Acoustic wave devices are widely used in modern electronics. At a high level, acoustic wave devices include a piezoelectric material in contact with one or more electrodes. Piezoelectric materials acquire a charge when compressed, twisted, or distorted, and similarly compress, twist, or distort when a charge is applied to them. Accordingly, when an alternating electrical signal is applied to the one or more electrodes in contact with the piezoelectric material, a corresponding mechanical signal (i.e., an oscillation or vibration) is transduced therein. Based on the characteristics of the one or more electrodes on the piezoelectric material, the properties of the piezoelectric material, and other factors such as the shape of the acoustic wave device and other structures provided on the device, the mechanical signal transduced in the piezoelectric material exhibits a frequency dependence on the alternating electrical signal. Acoustic wave devices leverage this frequency dependence to provide one or more functions.

Exemplary acoustic wave devices include surface acoustic wave (SAW) resonators and bulk acoustic wave (BAW) resonators, which are increasingly used to form filters used in the transmission and reception of radio frequency (RF) signals for communication. The widespread use of SAW filters is due to, at least in part, the fact that SAW filters exhibit low insertion loss with good rejection, can achieve broad bandwidths, and are a small fraction of the size of traditional cavity and ceramic filters. As with any electronic device, performance characteristics of a SAW device relative to a targeted application can impact the overall performance of a system. Due to the stringent demands placed on filters for modern RF communication systems, acoustic wave devices for these applications must provide a high quality factor (Q), wide bandwidths, a high electromechanical coupling coefficient (k2), favorable temperature coefficient of frequency (TCF), and suppression of out of band spurious modes for a variety of different applications with different operating conditions.

The art continues to seek improved acoustic wave devices that are capable of overcoming challenges associated with conventional devices.

### SUMMARY

The present disclosure relates to acoustic wave devices, and particularly to piezoelectric layer arrangements in acoustic wave devices and related methods. Acoustic wave devices are disclosed that include a piezoelectric layer on a carrier substrate. The piezoelectric layer is formed with a thickness that is varied or shaped across different portions of the carrier substrate. Different piezoelectric layer thicknesses on a common carrier substrate may be provided for different surface acoustic wave (SAW) filter structures that are formed monolithically, for different sets of resonators within a single filter structure, and for different regions within a single SAW device in one or more of the transverse direction or the propagation directions. Shaping piezoelectric layers may include selectively removing or adding portions of the piezoelectric layer. In this manner, piezoelectric layer thicknesses at different hierarchy levels within SAW devices and filters may be tailored to provide different acoustic resonator properties without requiring separately formed devices on separate substrates.

In one aspect, a SAW device comprises: a carrier substrate; a piezoelectric layer on the carrier substrate, wherein a first portion of the piezoelectric layer has a first thickness as measured in a direction perpendicular to the carrier substrate, a second portion of the piezoelectric layer has a second thickness as measured in the direction perpendicular to the carrier substrate, and wherein the first thickness is different than the second thickness; and at least one electrode on a surface of the piezoelectric layer opposite the carrier substrate. In certain embodiments, the at least one electrode comprises a plurality of electrodes on the piezoelectric layer that define a first SAW filter structure and a second SAW filter structure on the carrier substrate, and the first SAW filter structure comprises the first portion of the piezoelectric layer and the second SAW filter structure comprises the second portion of the piezoelectric layer. In certain embodiments, the first SAW filter structure and the second SAW filter structure each comprise a number of SAW resonators. In certain embodiments, the first SAW filter structure and the second SAW filter structure further comprise a number of SAW coupled resonator filters. In certain embodiments, the at least one electrode comprises a plurality of electrodes on the piezoelectric layer that define a SAW filter structure, and the SAW filter structure comprises a plurality of SAW resonators. The plurality of SAW resonators may form a number of series resonators that comprise the first portion of the piezoelectric layer and a number of shunt resonators that comprise the second portion of the piezoelectric layer. In certain embodiments, the at least one electrode comprises an interdigitated transducer (IDT) and the SAW device further comprises first and second reflective structures that are arranged on the piezoelectric layer such that the IDT is positioned between the first reflective structure and the second reflective structure. In certain embodiments, the IDT is arranged on the first portion of the piezoelectric layer and the first and second reflective structures are arranged on the second portion of the piezoelectric layer. In certain embodiments, the first portion of the piezoelectric layer is registered with individual electrode fingers of the IDT and the second portion of the piezoelectric layer is registered between adjacent pairs of the individual electrode fingers. In certain embodiments, the first portion of the piezoelectric layer and the second portion of the piezoelectric layer are arranged along a transverse direction of the SAW device such that an electrode finger of the IDT is arranged on both of the first portion of the piezoelectric layer and the second portion of the piezoelectric layer. In certain embodiments, a third portion of the piezoelectric layer comprises a third thickness as measured in a direction perpendicular to the carrier substrate, wherein the third thickness is different that the first thickness and the second thickness, and the electrode finger is arranged on the first, second, and third portions of the piezoelectric layer.

In another aspect, a method comprises: providing a carrier substrate; providing a piezoelectric layer on the carrier substrate; shaping the piezoelectric layer such that a first portion of the piezoelectric layer is formed with a first thickness as measured in a direction perpendicular to the carrier substrate, a second portion of the piezoelectric layer is formed with a second thickness as measured in the direction perpendicular to the carrier substrate, and wherein the first thickness is different than the second thickness; and providing at least one electrode on a surface of the piezoelectric layer opposite the carrier substrate. In certain embodiments, shaping the piezoelectric layer comprises applying a selective removal process to form the second portion of the piezoelectric layer such that the second thickness is less than the first thickness. In certain embodiments, the selective removal process comprises forming a patterned etch mask over the first portion of the piezoelectric layer and selectively etching the second portion of piezoelectric layer. In certain embodiments, the at least one electrode is formed on the second portion of the piezoelectric layer. In certain embodiments, the at least one electrode comprises a plurality of electrodes on the piezoelectric layer that define a first SAW filter structure and a second SAW filter structure on the carrier substrate, and the first SAW filter structure comprises the first portion of the piezoelectric layer and the second SAW filter structure comprises the second portion of the piezoelectric layer. In certain embodiments, the first SAW filter structure and the second SAW filter structure each comprise a number of SAW resonators. In certain embodiments, the at least one electrode comprises a plurality of electrodes on the piezoelectric layer that define a SAW filter structure, and the SAW filter structure comprises a plurality of SAW resonators. In certain embodiments, the plurality of SAW resonators form a number of series resonators that comprise the first portion of the piezoelectric layer and a number of shunt resonators that comprise the second portion of the piezoelectric layer. In certain embodiments, the at least one electrode comprises an interdigitated transducer (IDT) and the SAW device further comprises first and second reflective structures that are arranged on the piezoelectric layer such that the IDT is positioned between the first reflective structure and the second reflective structure. In certain embodiments, the IDT is arranged on the first portion of the piezoelectric layer and the first and second reflective structures are arranged on the second portion of the piezoelectric layer. In certain embodiments, the first portion of the piezoelectric layer and the second portion of the piezoelectric layer are arranged along a transverse direction of the SAW device such that an electrode finger of the IDT is arranged on both of the first portion of the piezoelectric layer and the second portion of the piezoelectric layer.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a perspective view illustration of a representative surface acoustic wave (SAW) device.

FIG. 2 is a representative cross-section for the SAW device of FIG. 1.

FIG. 3A is a plot illustrating simulation results that demonstrate how a coupling coefficient k2 of a SAW resonator changes with different piezoelectric layer thicknesses.

FIG. 3B is a plot illustrating the response of k2 for different piezoelectric layer thicknesses based on measured SAW resonator responses.

FIG. 4A illustrates a top view of a portion of a wafer after SAW filter fabrication and before dicing according to principles of the present disclosure, and an exploded box in FIG. 4A is illustrated to provide details of an individual SAW device that may be singulated from the wafer after dicing.

FIG. 4B illustrates a top view of an alternative configuration of the wafer and individual SAW device of FIG. 4A.

FIG. 4C is a top view illustration for another alternative configuration of the SAW device of FIG. 4A.

FIG. 5 is a schematic diagram illustrating embodiments of a ladder filter as applied to principles of the present disclosure.

FIG. 6 is a cross-section illustration for an individual SAW device where the piezoelectric layer is formed with different thicknesses along a wave propagation direction according to principles of the present disclosure.

FIG. 7A is a cross-section illustration for a SAW device that is similar to the SAW device of FIG. 6, but where different thickness portions may also be provided between electrode fingers of an interdigitated transducer (IDT) according to principles of the present disclosure.

FIG. 7B is a cross-section illustration for a SAW device that is similar to the SAW device of FIG. 7A, but with a reverse configuration of the piezoelectric layer that is underneath the IDT.

FIG. 8A is a top-view illustration for a SAW device where the piezoelectric layer is formed with different thicknesses along a transverse direction of the SAW device according to principles of the present disclosure.

FIG. 8B is a top-view illustration for a SAW device where the piezoelectric layer is formed with different thicknesses along a transverse direction in an alternative configuration to the SAW device of FIG. 8A.

FIG. 8C is a top-view illustration for a SAW device where the piezoelectric layer is formed with different thicknesses along a propagation direction of the SAW device according to principles of the present disclosure.

FIG. 8D is a top-view illustration for a SAW device where the piezoelectric layer is formed with different thicknesses along the propagation direction in an alternative configuration to the SAW device of FIG. 8C.

FIG. 9A is a plot illustrating the resonance frequency and its dependence on piezoelectric layer thickness for finite element (FEM) simulations of an exemplary SAW resonator stack that is configured for B41 operation.

FIG. 9B is a plot illustrating the resulting coupling coefficient and its dependence on piezoelectric layer thickness for the FEM simulations.

FIG. 9C is a plot illustrating the resulting quality factor at anti-resonance and its dependence on piezoelectric layer thickness for the FEM simulations.

FIG. 10A is a plot illustrating temperature coefficient of frequency at resonance (TCFs) and temperature coefficient of frequency at antiresonance (TCFp) measurements across a range of piezoelectric layer thicknesses values.

FIG. 10B is a plot that illustrates the difference between TCFs and TCFp (ΔTCF) values of FIG. 10A.

FIG. 11A is a cross-section illustration at a fabrication step where a SAW device is provided with a piezoelectric layer having a first thickness on a substrate and with an intermediate layer therebetween.

FIG. 11B is a cross-section illustration at a subsequent fabrication step where an etch mask is selectively applied over portions of the piezoelectric layer and other portions of the piezoelectric layer that are uncovered by the etch mask are selectively removed.

FIG. 11C is a cross-section illustration at a subsequent fabrication step where the etch mask is removed and remaining SAW structures are formed on the piezoelectric layer.

FIG. 12A is an illustration of a removal map that indicates differences in thickness across a large area bonded wafer that includes a piezoelectric layer.

FIG. 12B is an illustration of an intended or theoretical post-etch map for an idealized etching process applied to the wafer of FIG. 12A.

FIG. 12C is a measured post-etch map for the wafer of FIG. 12A.

FIG. 13A is a wafer map that indicates relative wafer locations for trimmed and untrimmed resonator device locations chosen for quality factor measurements from the wafer of FIG. 12C.

FIG. 13B is a graph that indicates the resonators from trimmed and untrimmed wafer areas of FIG. 13A show comparable quality factors.

FIG. 13C is a graph that indicates no significant decrease of the quality factor based on amount of piezoelectric layer removed for the resonators from the trimmed and untrimmed wafer areas of FIG. 13A.

FIG. 13D is a graph that indicates the piezoelectric layer thickness variation between the devices is comparable between the trimmed and untrimmed wafer areas of FIG. 13A.

FIG. 13E is a graph that indicates that the resonators from trimmed and untrimmed wafer areas of FIG. 13A show comparable antiresonance quality factors.

FIG. 13F is a graph that indicates no significant decrease of the antiresonance quality factor based on the amount of piezoelectric layer removed for the resonators from the trimmed and untrimmed wafer areas of FIG. 13A.

FIG. 13G is a graph that indicates the piezoelectric layer thickness variation between the devices is comparable between the trimmed and untrimmed wafer areas of FIG. 13A.

FIG. 13H is a graph that indicates that the resonators from trimmed and untrimmed wafer areas of FIG. 13A show comparable coupling.

FIG. 13I is a graph that indicates no significant decrease of the antiresonance quality factor based on the amount of piezoelectric layer removed for the resonators from the trimmed and untrimmed wafer areas of FIG. 13A.

FIG. 13J is a graph that indicates the piezoelectric layer thickness variation between the filtered devices is comparable between the trimmed and untrimmed wafer areas of FIG. 13A.

FIG. 14A is a wafer map that indicates relative wafer locations for trimmed and untrimmed resonator device locations chosen for quality factor measurements in a similar manner as FIG. 13A, but for higher frequency devices.

FIG. 14B is a graph that indicates the resonators from trimmed and untrimmed wafer areas of FIG. 14A show comparable quality factors.

FIG. 14C is a graph that indicates no significant decrease of the quality factor based on amount of piezoelectric layer removed for the resonators from the trimmed and untrimmed wafer areas of FIG. 14A.

FIG. 14D is a graph that indicates the piezoelectric layer thickness variation between the filtered devices is comparable between the trimmed and untrimmed wafer areas of FIG. 14A.

FIG. 14E is a graph that indicates that the resonators from trimmed and untrimmed wafer areas of FIG. 14A show comparable antiresonance quality factors.

FIG. 14F is a graph that indicates no significant decrease of the antiresonance quality factor based on the amount of piezoelectric layer removed for the resonators from the trimmed and untrimmed wafer areas of FIG. 14A.

FIG. 14G is a graph that indicates the piezoelectric layer thickness variation between the devices is comparable between the trimmed and untrimmed wafer areas of FIG. 14A.

FIG. 14H is a graph that indicates that the resonators from trimmed and untrimmed wafer areas of FIG. 14A show comparable coupling.

FIG. 14I is a graph that indicates no significant decrease of the antiresonance quality factor based on the amount of piezoelectric layer removed for the resonators from the trimmed and untrimmed wafer areas of FIG. 14A.

FIG. 14J is a graph that indicates the piezoelectric layer thickness variation between the filtered devices is comparable between the trimmed and untrimmed wafer areas of FIG. 14A.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to acoustic wave devices, and particularly to piezoelectric layer arrangements in acoustic wave devices and related methods. Acoustic wave devices are disclosed that include a piezoelectric layer on a carrier substrate. The piezoelectric layer is formed with a thickness that is varied or shaped across different portions of the carrier substrate. Different piezoelectric layer thicknesses on a common carrier substrate may be provided for different surface acoustic wave (SAW) filter structures that are formed monolithically, for different sets of resonators within a single filter structure, and for different regions within a single SAW device in one or more of the transverse direction or the propagation directions. Shaping piezoelectric layers may include selectively removing or adding portions of the piezoelectric layer. In this manner, piezoelectric layer thicknesses at different hierarchy levels within SAW devices and filters may be tailored to provide different acoustic resonator properties without requiring separately formed devices on separate substrates.

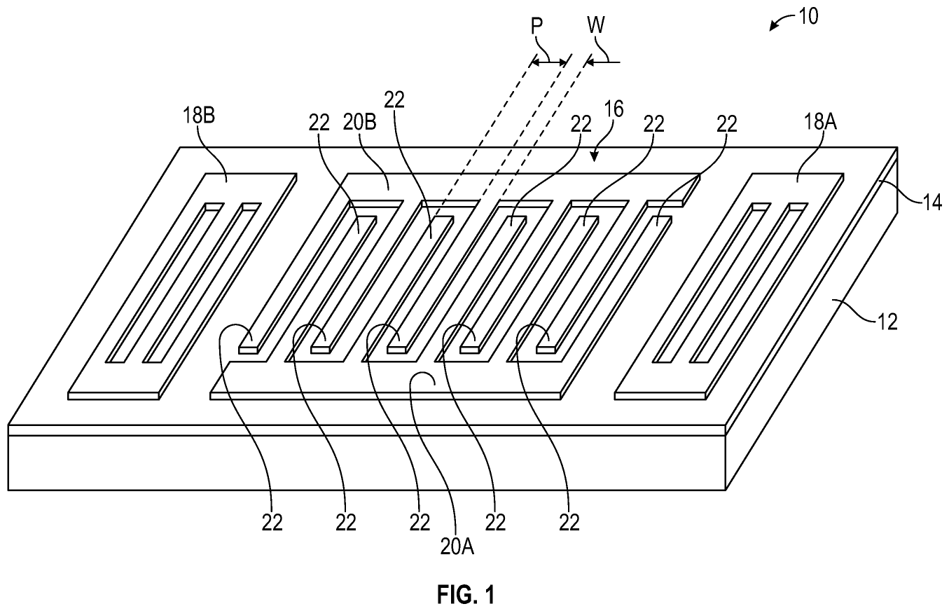

Before describing particular embodiments of the present disclosure further, a general discussion of SAW devices is provided. FIG. 1 is a perspective view illustration of a representative SAW device 10. The SAW device 10 includes a substrate 12, a piezoelectric layer 14 on the substrate 12, an interdigitated transducer (IDT) 16 on a surface of the piezoelectric layer 14 opposite the substrate 12, a first reflector structure 18A on the surface of the piezoelectric layer 14 adjacent to the IDT 16, and a second reflector structure 18B on the surface of the piezoelectric layer 14 adjacent to the IDT 16 opposite the first reflector structure 18A. In certain aspects, the substrate 12 may be referred to as a carrier substrate and the overall SAW device 10 may be referred to as a guided SAW device.

The IDT 16 includes a first electrode 20A and a second electrode 20B, each of which include a number of electrode fingers 22 that are interleaved with one another as shown. The first electrode 20A and the second electrode 20B may also be referred to as comb electrodes. A lateral distance between adjacent electrode fingers 22 of the first electrode 20A and the second electrode 20B defines an electrode pitch P of the IDT 16. The electrode pitch P may at least partially define a center frequency wavelength A of the SAW device 10, where the center frequency is the primary frequency of mechanical waves generated in the piezoelectric layer 14 by the IDT 16. For the IDT 16 as shown in FIG. 1 where the electrode pitch P is the same for all electrode fingers 22, the center frequency wavelength A is equal to twice the electrode pitch P. For a double electrode IDT 16, the center frequency wavelength A is equal to four times the electrode pitch P. A finger width W of the adjacent electrode fingers 22 over the electrode pitch P may define a metallization ratio, or duty factor, of the IDT 16, which may dictate certain operating characteristics of the SAW device 10.

In operation, an alternating electrical input signal provided at the first electrode 20A is transduced into a mechanical signal in the piezoelectric layer 14, resulting in one or more acoustic waves therein. In the case of the SAW device 10, the resulting acoustic waves are predominately surface acoustic waves. As discussed above, due to the electrode pitch P and the metallization ratio of the IDT 16, the characteristics of the material of the piezoelectric layer 14, and other factors, the magnitude and frequency of the acoustic waves transduced in the piezoelectric layer 14 are dependent on the frequency of the alternating electrical input signal. This frequency dependence is often described in terms of changes in the impedance and/or a phase shift between the first electrode 20A and the second electrode 20B with respect to the frequency of the alternating electrical input signal. An alternating electrical potential between the two electrodes 20A and 20B creates an electrical field in the piezoelectric material which generate acoustic waves. The acoustic waves travel at the surface and eventually are transferred back into an electrical signal between the electrodes 20A and 20B. The first reflector structure 18A and the second reflector structure 18B reflect the acoustic waves in the piezoelectric layer 14 back towards the IDT 16 to confine the acoustic waves in the area surrounding the IDT 16.

The substrate 12 may comprise various materials including glass, sapphire, quartz, silicon (Si), or gallium arsenide (GaAs) among others, with Si being a common choice. The piezoelectric layer 14 may be formed of any suitable piezoelectric material(s). In certain embodiments described herein, the piezoelectric layer 14 is formed of lithium tantalate (LT), or lithium niobate (LiNbO₃), but is not limited thereto. In certain embodiments, the piezoelectric layer 14 is thick enough or rigid enough to function as a piezoelectric substrate. Accordingly, the substrate 12 in FIG. 1 may be omitted. Those skilled in the art will appreciate that the principles of the present disclosure may apply to other materials for the substrate 12 and the piezoelectric layer 14. The IDT 16, the first reflector structure 18A, and the second reflector structure 18B may comprise one or more of aluminum (Al), copper (Cu), titanium (Ti), platinum (Pt), and alloys thereof in either single or multiple layer arrangements. While not shown to avoid obscuring the drawings, additional passivation layers, frequency trimming layers, or any other layers may be provided over all or a portion of the exposed surface of the piezoelectric layer 14, the IDT 16, the first reflector structure 18A, and the second reflector structure 18B. Such additional passivation layers may be provided for temperature compensation purposes and/or improved thermal conductivity, among other reasons. Further, one or more layers may be provided between the substrate 12 and the piezoelectric layer 14 in various embodiments.

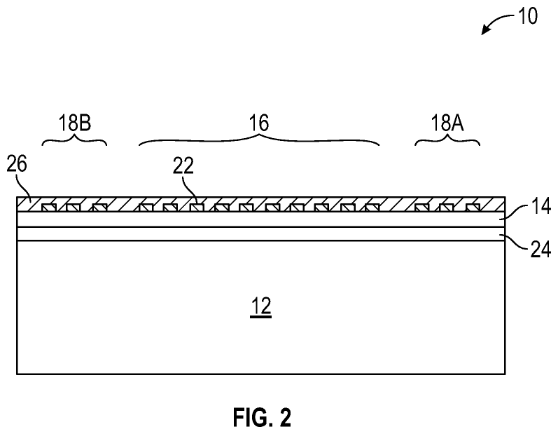

FIG. 2 is a representative cross-section for the SAW device 10 of FIG. 1. In order to suppress this bulk radiation and associated propagation loss, the SAW device 10 may be provided with a layered substrate structure where the piezoelectric layer 14, which may also be referred to herein as a piezoelectric material, or film, is bonded or deposited on the substrate 12. The SAW device 10 may include the IDT 16, the first reflector structure 18A, and the second reflector structure 18B as previously described. If a bulk acoustic wave (BAW) velocity of the substrate 12 in a direction of propagation for the SAW device 10 is suitably large, then acoustic energy may be guided within the piezoelectric layer 14, and loss into the bulk (i.e., the loss into the substrate 12) can be reduced or cancelled. An intermediate layer 24, or a plurality of intermediate layers 24, may be arranged between the piezoelectric layer 14 and the carrier substrate 12. The intermediate layer 24 may be used to improve one or more of the acoustic guiding or the piezoelectric coupling, temperature compensation, thermal conductivity, and stress and/or strain mitigation, or it may be required for a particular manufacturing process. In certain embodiments, the intermediate layer 24 may include one or more dielectric layers, metallic layers, piezoelectric layers and combinations thereof. In one example, the intermediate layer 24 may comprise one or more layers of silicon dioxide (SiO₂) and/or silicon nitride (SiN). The SAW device 10 may further comprise a dielectric layer 26, or a plurality of dielectric layers 26, on the IDT 16, the first reflector structure 18A, the second reflector structure 18B, and exposed surfaces of the piezoelectric layer 14. As illustrated, the IDT 16, the first reflector structure 18A, and the second reflector structure 18B may be embedded within the dielectric layer 26. In certain embodiments, the dielectric layer 26 may comprise one or more layers of SiO₂, SiN, and an oxide of aluminum to provide passivation.

SAW devices, or SAW resonators, based on layered substrates are generally suitable for use as filters across challenging bands, such as mid/high band (MHB) frequency ranges, among other challenging bands. Depending on the particular band, SAW device configurations with different piezoelectric layer configurations are utilized to provide different acoustic resonator properties. Acoustic resonator properties for SAW devices that are important for high performance acoustic filters and related products include coupling coefficient (k2), quality factor (Q), temperature coefficient of frequency (TCF) and suppression of out-of-band spurious modes, among others. In conventional guided SAW devices, a constant piezoelectric layer thickness is typically provided for all resonators and filters which are formed on a same wafer and accordingly, there can be trade-offs between important acoustic resonator properties. These trade-offs can potentially limit the performance of the resulting SAW devices and filters. Alternatively, different SAW resonators and filters may be assembled together that are provided from different wafers to address such trade-offs, but not without increased costs and manufacturing complexity associated with separately formed devices. In such configurations, spacing requirements from having different SAW resonators and filters that are assembled together may require longer interconnect lengths that lead to additional losses.

According to principles of the present disclosure, piezoelectric layer thicknesses at different hierarchy levels within SAW devices and filters may be tailored without requiring separately formed devices on separate substrates. In this regard, SAW devices and filters with different properties may be formed closer together with reduced interconnect losses as compared to arrangements of separately formed SAW devices and filters. In certain aspects, different piezoelectric layer thicknesses may be provided for different SAW filter structures that are formed monolithically on a common substrate such that different ones of the filter structures are tailored for acoustic resonator properties of different frequency bands. In certain aspects, different piezoelectric layer thicknesses may be provided for different sets of resonators (e.g., shunt and series resonators) within a filter. In still further aspects, different piezoelectric layer thicknesses may be provided for different regions within a single SAW device in one or more of the transverse direction or the propagation directions. For example, different piezoelectric layer thicknesses may be provided for reflectors relative to IDTs or for certain areas within a coupled-resonator filter (CRF). In order to implement such tailored piezoelectric layer thicknesses, a piezoelectric layer of a bonded wafer may be patterned before forming the electrode structure on top of the piezoelectric layer. In other implementations, the piezoelectric layer may be patterned after the electrode structure is provided. In either implementation, an additional degree of freedom is provided that is not available for conventional devices. While embodiments of the present disclosure are described for guided SAW devices on layered substrates, the principles of the present disclosure are also applicable to other SAW technologies relying on bulk piezoelectric wafers (e.g. LT-SAWs or temperature-compensated SAWs) as well as BAW technologies.

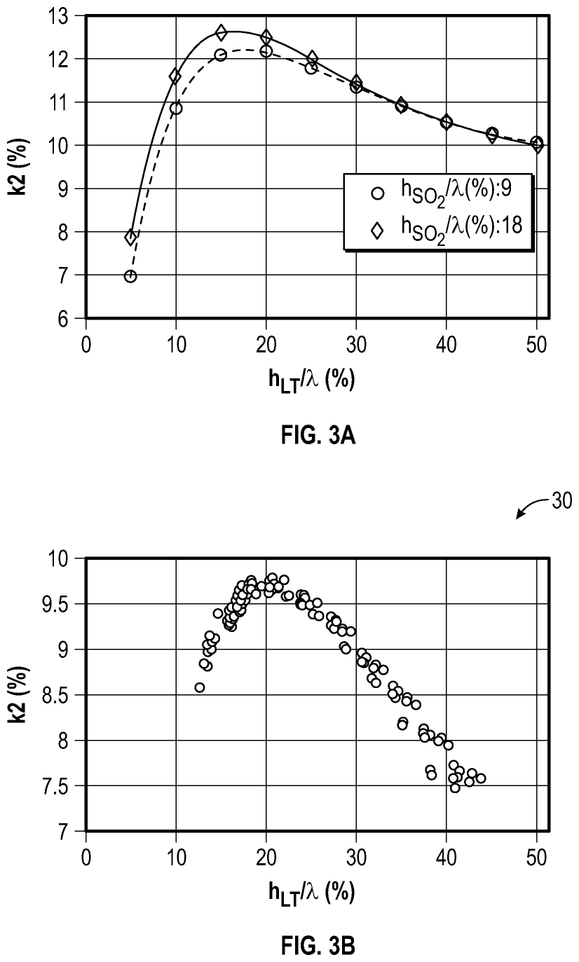

FIG. 3A is a plot 28 illustrating simulation results that demonstrate how the coupling coefficient k2 of a SAW resonator changes with different piezoelectric layer thicknesses. For the purposes of the simulation, an exemplary structure for the SAW resonator was selected that included a silicon substrate (e.g., 12 of FIG. 2), a buried SiO₂ layer (e.g., 24 of FIG. 2), a piezoelectric layer (e.g., 14 of FIG. 2) that comprises LT, an IDT (e.g., 16 of FIG. 2) formed of aluminum copper, and a dielectric layer (e.g., 26 of FIG. 2) formed of SiN. In the simulation, the thickness of the piezoelectric layer

$$( \frac{{h}_{LT}}{λ} ( \% ) )$$

was varied with all other structural aspects of the SAW resonator kept constant for two different thicknesses of the buried SiO₂ layer

$$( \frac{{h}_{{SiO}_{2}}}{λ} ( \% ) = 9 and \frac{{h}_{{SiO}_{2}}}{λ} ( \% ) = 18 ) .$$

As illustrated, the k2 depends slightly on the buried SiO₂ layer thickness. While the SiO₂ layer may be of importance for temperature compensation, stress/strain mitigation, and reduced coupling to an electrically conductive channel at an interface or within the device, the piezoelectric layer thickness can act as a major parameter for tailoring the coupling of a SAW resonator for a certain application.

FIG. 3B is a plot 30 illustrating the response of k2 for different piezoelectric layer thicknesses based on measured SAW resonator responses. As illustrated, the measurement results confirm the simulation results of FIG. 3A, demonstrating that the coupling coefficient k2 of a SAW resonator may directly correlate with the thickness of the piezoelectric layer. By using different piezoelectric layer thicknesses, different working points for sets of SAW resonators may be chosen. This may enable separate optima for series and shunt resonators formed on a common substrate. For example, smaller coupling but higher Q may be provided for a steep transition of one of two filter skirts, while another set of resonators may be structured to provide a large bandwidth. According to principles of the present disclosure, a SAW device with two resonators may be formed monolithically on a same substrate where one of the resonators is provided with a

$$( \frac{{h}_{LT}}{λ} ( \% ) )$$

value of 20 and the other resonator is provided with a

$$( \frac{{h}_{LT}}{λ} ( \% ) )$$

of 40. As such, this may enable SAW device and filter structures that avoid using other techniques, such as de-coupling capacitors (with potentially low Q) in parallel to resonators, thereby saving space on the die and improving filter performance.

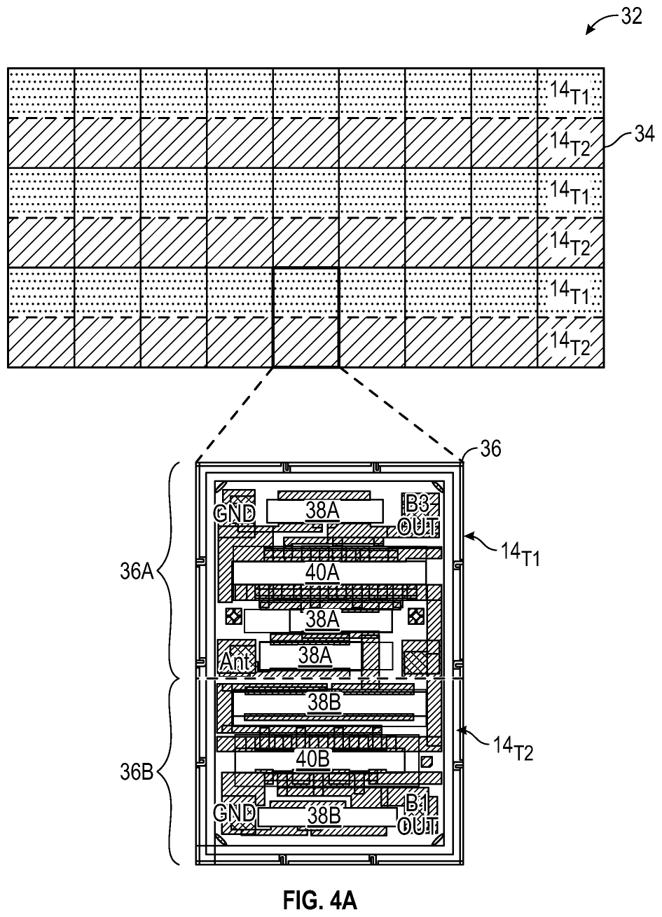

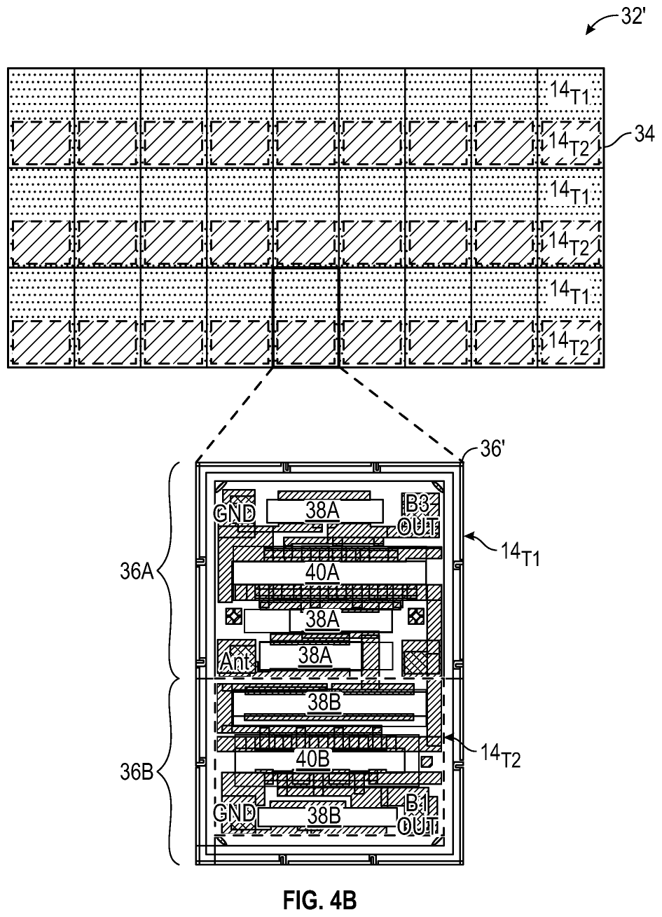

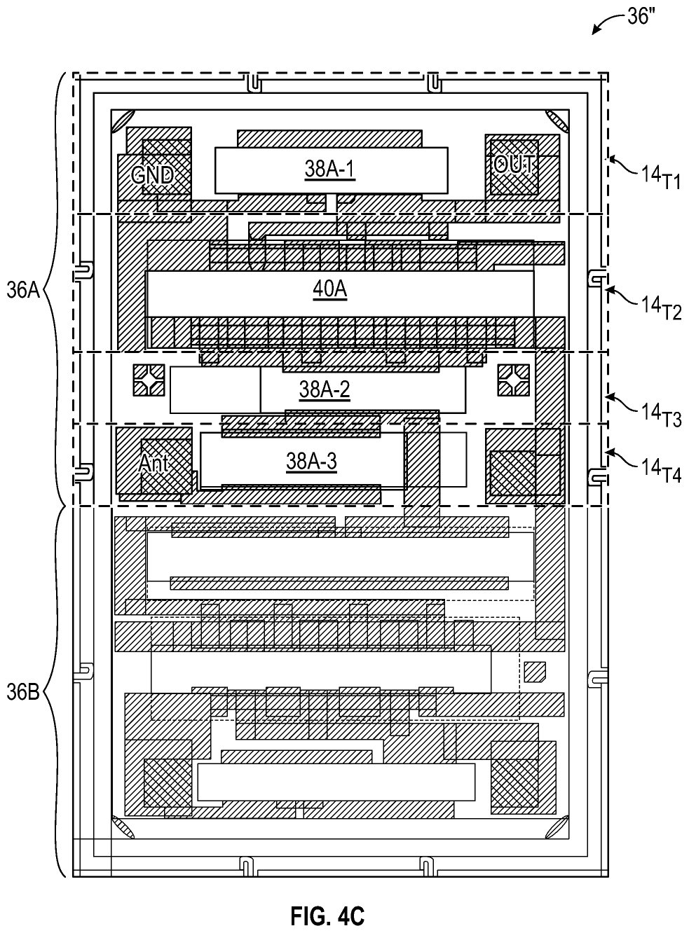

FIG. 4A illustrates a top view of a portion of a device wafer 32 after SAW filter fabrication and before dicing according to principles of the present disclosure. An exploded box in FIG. 4A is illustrated to provide details of an individual SAW device 36 that may be singulated from the device wafer 32 after dicing. The SAW device 36 includes a monolithic integration of first and second SAW filters 36A and 36B, where the first SAW filter 36A has a different piezoelectric layer thickness than that of the SAW filter 36B. By way of example, the first SAW filter 36A may be configured as a radio frequency receive (Rx) filter for operation in Band 3 of the MHB frequency range with an operating frequency target of 1842.5 megahertz (MHz), and the second SAW filter 36B may be configured as an Rx filter for operation in Band 1 of the MHB frequency range with an operating frequency target of 2140 MHz. The first SAW filter 36A and the second SAW filter 36B may include various numbers of SAW resonators 38A, 38B and SAW coupled resonator filters (SAW CRFs) 40A, 40B. By way of example, the thickness of the piezoelectric layer in the first SAW filter 36A (designated as 14_{T1}) may be set at 660 nanometers (nm) while the thickness of the piezoelectric layer in the second SAW filter 36B (designated as 14_{T2}) may be set at 500 nm, thereby forming a step height of 160 nm therebetween. In this manner, the first and second SAW filters 36A and 36B with different filter topologies may be formed on a common substrate (e.g., 12 of FIG. 2) with different piezoelectric layer thicknesses according to principles of the present disclosure. At the wafer level, the first and second thicknesses of the piezoelectric layer (14_{T1} and 14_{T2}) may appear as stripes across the device wafer 32. In still further embodiments, the first and second thicknesses of the piezoelectric layer (14_{T1} and 14_{T2}) may be formed in a checkerboard pattern when the piezoelectric layer exhibits 180 degree rotational symmetry around surface normal such that the position of the SAW filters 36A and 36B may alternate from SAW device 36 to SAW device 36.

In certain embodiments, the piezoelectric layer may be selectively removed or selectively added in different locations across the device wafer 32 that correspond with the first and second SAW filters 36A and 36B. Selectively removing portions of the piezoelectric layer may include selectively etching the piezoelectric layer to form thinner regions (e.g., in the second SAW filter 36B). For example, an exemplary fabrication process may comprise applying a patterned etch and/or a patterned trim procedure to the piezoelectric layer of the device wafer 32. In certain embodiments, this piezoelectric material removal may be performed with commercial equipment, such as ion beam plasma tools which are commonly utilized within the standard SAW processes for trimming dielectric layers. Selectively adding portions of the piezoelectric layer may include selectively depositing or growing portions of the piezoelectric layer to form thicker regions (e.g., in the first SAW filter 36A). The fabrication steps described above may be repeated any number of times to provide different piezoelectric layer thicknesses across the device wafer 32 (or substrate 12 of FIG. 2 after singulation). In this manner, trade-offs between acoustic resonator properties may be tailored for implementation within a monolithic die that includes different numbers of SAW filter structures to provide smaller overall die sizes within a module, such as a diversity receive (DRx) module. In alternative fabrication step embodiments, the piezoelectric layer thickness may be altered with a tool that includes beam scanning capabilities, which may provide thickness gradients between regions of different thicknesses, in addition to discrete thickness steps.

FIG. 4B illustrates a top view of an alternative configuration of the wafer 32 of FIG. 4A, labeled 32′ in FIG. 4B. An exploded box in FIG. 4B is illustrated to provide details of a corresponding SAW device 36′, which is an alternative configuration for the individual SAW device 36 of FIG. 4A. In FIG. 4B, the different thickness 14_{T2} of the second portion of the piezoelectric layer is provided on only a portion of the SAW filter 36B. In this regard, the thickness 14_{T1} of the first portion of the piezoelectric layer is provided for the SAW filter 36A and along portions of the SAW filter 36B, such as around a perimeter of the SAW filter 36B. At the wafer level, the thickness 14_{T1} of the first portion of the piezoelectric layer may appear continuously across a wafer 32′ while the thickness 14_{T2} of the second portion of the piezoelectric layer may appear as a pattern of discontinuous regions.

FIG. 4C is a top view illustration for a SAW device 26″, which is an alternative configuration of the SAW device 36′ of FIG. 4A, labeled 36″ in FIG. 4C. Rather than having a different piezoelectric layer thickness for the entire first SAW filter 36A and the entire second SAW filter 36B, different piezoelectric layer thicknesses may be provided within one of the SAW filters 36A, 36B. By way of example, in the SAW device 36″ of FIG. 4C, the SAW filter 36A may include a different piezoelectric layer thickness for each of SAW resonators 38A-1 to 38A-3 and for the SAW CRF 40A (designated as 14_{T1} to 14_{T4} (e.g., 14_{T1}≠14_{T2}≠14_{T3}≠14_{T4}). In other embodiments, each of the SAW resonators 38A-1 to 38A-3 may have a same piezoelectric layer thickness (e.g., 14_{T1}=14_{T3}=14_{T4}) that is different than the piezoelectric layer thickness (e.g. 14_{T2}) of the SAW CRF 40A.

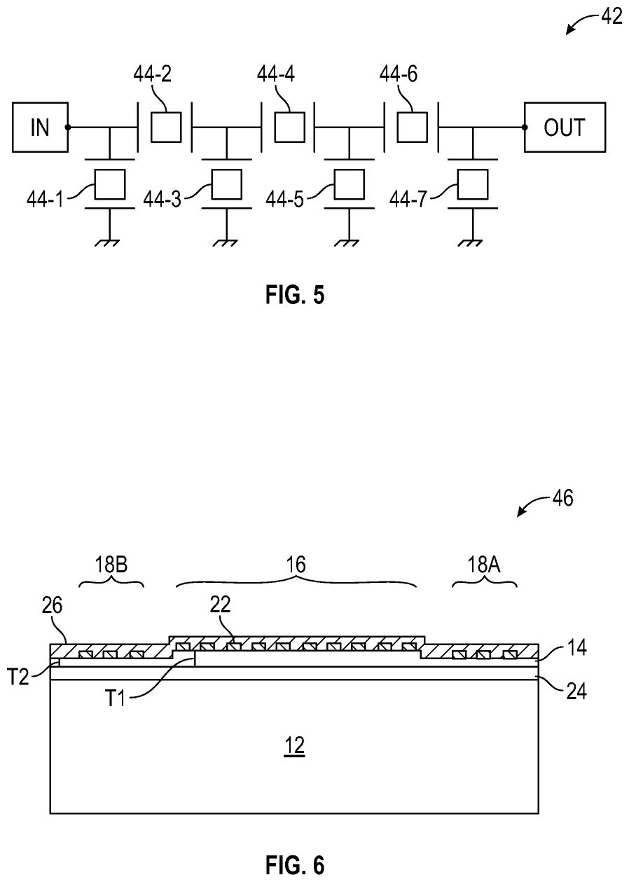

FIG. 5 is a schematic diagram illustrating embodiments of a ladder filter 42 as applied to principles of the present disclosure. As shown, the ladder filter 42 may include several SAW resonators 44-1 to 44-7 that are connected inside an electrical circuit. Each of the SAW resonators 44-1 to 44-1 may be formed monolithically on a common substrate as previously described. In general, the ladder filter 42 is designed such that shunt resonators (i.e., the SAW resonators 44-1, 44-3, 44-5, and 44-7) have an antiresonance frequency close to the center frequency of the ladder filter 42 and series resonators (i.e., the SAW resonators 44-2, 44-4, and 44-6) are designed to have their resonance frequency close to the center frequency of the ladder filter 42. Thus, at the center frequency, the shunt resonators act as open circuits, the series resonators act as short circuits, and there is a direct connection between an input and an output of the ladder filter 42. At their resonance frequency, the shunt resonators act as short circuits, producing a notch in the transfer function of the ladder filter 42 below the passband. Similarly, at their antiresonance frequency, the series resonators act as open circuits and produce a notch above the stopband. In order to tailor trade-offs between acoustic resonator properties, the shunt SAW resonators (44-1, 44-3, 44-5, and 44-7) may be arranged with a different piezoelectric thickness than the series SAW resonators (44-2, 44-4, and 44-6). Depending on the application, the piezoelectric layer may be thicker or thinner in the shunt SAW resonators relative to the series SAW resonators. Many alternative configurations for the ladder filter 42, not shown on the figure, are also possible. For example and not limited to, in some cases, the ladder filter 42 may have different numbers of resonators and/or have several consecutive series resonators or shunt resonators.

FIG. 6 is a cross-section illustration for an individual SAW device 46 where the piezoelectric layer 14 is formed with different thicknesses along a wave propagation direction of the SAW device 46 according to principles of the present disclosure. As illustrated, the SAW device 46 is configured in a similar manner as the SAW device 10 of FIG. 2, but the piezoelectric layer 14 is not formed with a constant thickness. Rather, a first thickness T1 of the piezoelectric layer 14 that is registered with the IDT 16 is different than a second thickness T2 of the piezoelectric layer 14 that is registered with the first and second reflector structures 18A and 18B. As illustrated, the first thickness T1 and the second thickness T2 are measured in a direction perpendicular to the substrate 12 and the intermediate layer 24. By way of example, the first thickness T1 in FIG. 6 is greater than the second thickness T2. In other embodiments, the thicknesses may be reversed such that the second thickness T2 is greater than the first thickness T1. By enabling the second thickness T2 to be different from the first thickness T1, the SAW device 46 may be provided with an additional degree of freedom for tailoring reflectivity and confinement response for reduced leakage and loss in various applications. For manufacturing the SAW device 46, portions of the piezoelectric layer 14 may be selectively removed to form the second thickness T2 or portions of the piezoelectric layer 14 may be selectively added to form the first thickness T1. In either case, the piezoelectric layer 14 may be provided with the first thickness T1 and the second thickness T2 before the IDT 16 and the reflector structures 18A, 18B are formed and patterned on the piezoelectric layer 14.

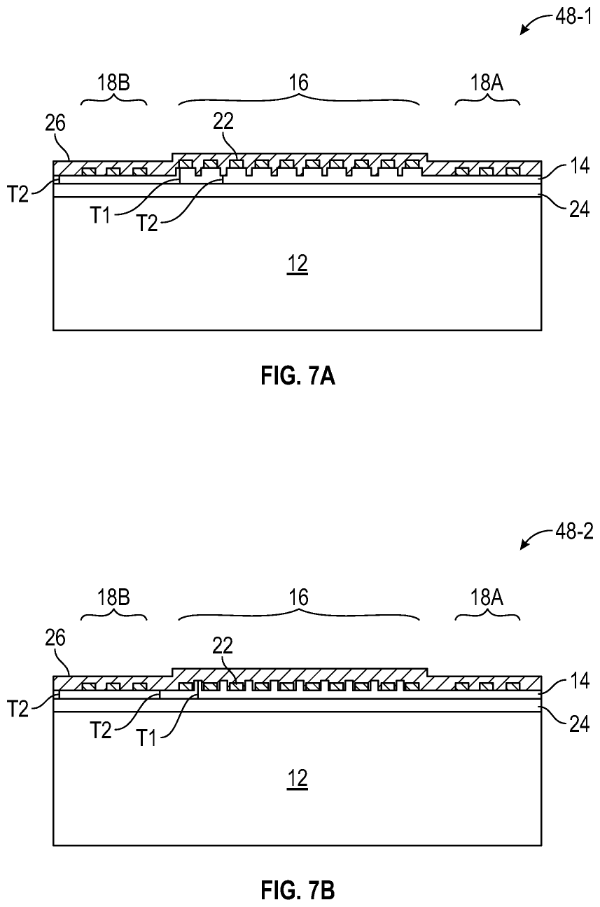

FIG. 7A is a cross-section illustration for a SAW device 48-1 that is similar to the SAW device 46 of FIG. 6, but where the second thickness T2 may also be provided between individual pairs of the electrode fingers 22 of the IDT 16 according to principles of the present disclosure. In this manner, the IDT 16 may be formed first on the piezoelectric layer 14, followed by selectively removing portions of the piezoelectric layer 14 that are registered between the electrode fingers 22 of the IDT 16. An intermediate fabrication step may include application of a mask over the electrode fingers 22 of the IDT 16 to sufficiently protect the IDT 16 during the removal step for the piezoelectric layer 14. In this manner, portions of the piezoelectric layer 14 with the first thickness T1 are registered with each individual electrode finger 22 and portions of the piezoelectric layer 14 with the second thickness T2 are registered between adjacent pairs of the electrode fingers 22. As illustrated, other portions of the piezoelectric layer 14 that are registered with the reflector structures 18A, 18B may also be provided with the second thickness T2. In other embodiments for different reflectivity and confinement responses, the portions of the piezoelectric layer 14 that are registered with the reflector structures 18A, 18B may further be provided with a thickness that is different than both the first thickness T1 and the second thickness T2.

FIG. 7B is a cross-section illustration for a SAW device 48-2 that is similar to the SAW device 48-1 of FIG. 7A, but with a reverse configuration of the piezoelectric layer 14 that is underneath the IDT 16. In FIG. 7B, the reflector structures 18A, 18B and the IDT 16 are formed on portions of the piezoelectric layer 14 with the second thickness T2, and portions of the piezoelectric layer 14 with the first thickness T1 are registered between adjacent pairs of the electrode fingers 22. In further embodiments, the IDT 16 and corresponding electrode fingers 22 may be provided on portions of the piezoelectric layer 14 that have a different thickness than either thicknesses T1 or T2.

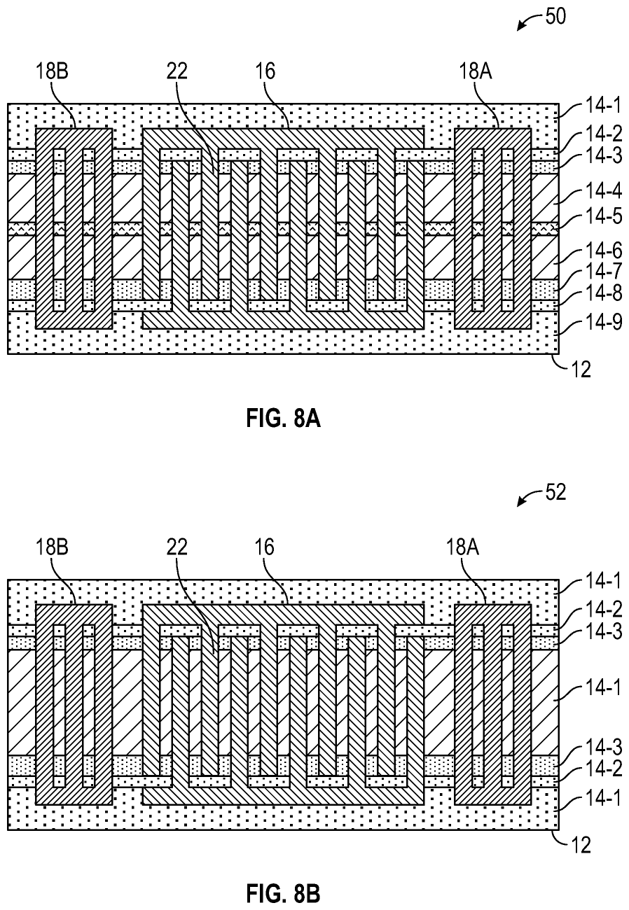

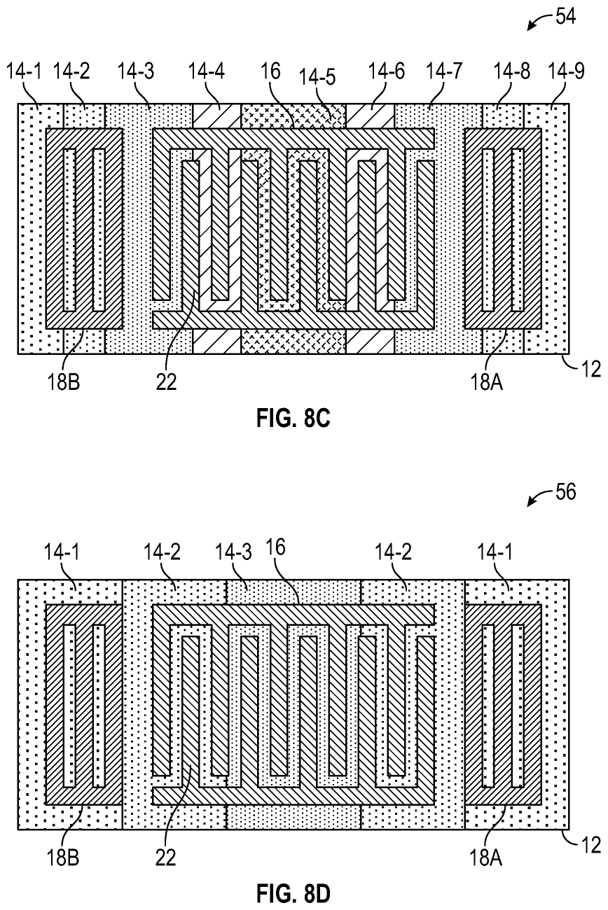

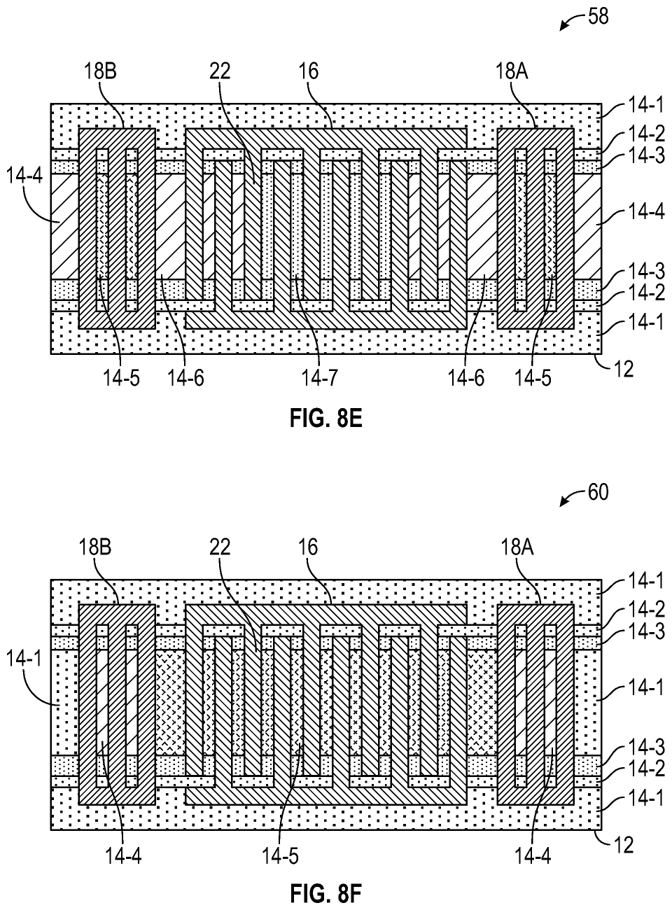

FIG. 8A is a top-view illustration for a SAW device 50 where the piezoelectric layer is formed with different thicknesses along a transverse direction of the SAW device 50 according to principles of the present disclosure. The SAW device 50 may include the IDT 16 and the reflector structures 18A, 18B as previously described. The piezoelectric layer may be formed with a varying thickness profile along the transverse direction such that different portions 14-1 to 14-9 of the piezoelectric layer have different thicknesses along a direction of the electrode fingers 22. In this manner, an individual one of the electrode fingers 22 may be arranged on at least two or more, or at least three or more, or at least seven or more or in a range from two to seven of the different portions 14-2 to 14-8 of the piezoelectric layer. Depending on the embodiment, the thicknesses of the piezoelectric layer portions 14-1 to 14-9 may progressively increase or decrease from across the transverse direction. In other embodiments, the thicknesses of the piezoelectric layer portions 14-1 to 14-9 may mirror one another above and below a horizontal center line of the SAW device 50 (e.g., along the propagation direction). FIG. 8B is a top-view illustration for a SAW device 52 where the piezoelectric layer is formed with different thicknesses along a transverse direction in an alternative configuration to the SAW device 50 of FIG. 8A. As illustrated, the SAW device 52 may be formed with piezoelectric layer thicknesses in a pattern across the transverse direction. By way of example, the thicknesses of the piezoelectric layer portions 14-1 to 14-3 of the SAW device 52 are formed with a symmetric pattern. The embodiments illustrated in FIGS. 8A and 8B demonstrate additional degrees of freedom within individual SAW devices that are provided by the ability to vary thicknesses of a piezoelectric layer. Such additional degrees of freedom may provide the ability to tailor different wave properties, such as velocity, coupling and frequency of the main resonator mode vs. other modes (e.g., spurious) at different positions across the device. These arrangements may be beneficial for tailoring spurious mode suppression such as suppressing Rayleigh modes when the main mode is a shear mode and suppressing shear modes when the main mode is in Rayleigh modes. Additionally, these arrangements may provide tailoring for suppression of transverse modes of the main mode and suppressing transverse modes of another spurious mode, and suppression of energy leakage in the transverse direction or into the layered substrate.

FIG. 8C is a top-view illustration for a SAW device 54 where the piezoelectric layer is formed with different thicknesses along a propagation direction of the SAW device 54 according to principles of the present disclosure. The piezoelectric layer may be formed with a varying thickness profile along the transverse direction such that different portions 14-1 to 14-9 of the piezoelectric layer have different thicknesses along the propagation direction. The thickness of each of the portions 14- to 14-9 of the piezoelectric layer may progressively increase or decrease along the propagation direction. In other embodiments, the thicknesses of the piezoelectric layer portions 14-1 to 14-9 may mirror one another to the right and left of a center line of the SAW device 54 (e.g., along the transverse direction). FIG. 8D is a top-view illustration for a SAW device 56 where the piezoelectric layer is formed with different thicknesses along the propagation direction in an alternative configuration to the SAW device 54 of FIG. 8C. As illustrated, the SAW device 56 may be formed with piezoelectric layer thicknesses in a pattern across the propagation direction. By way of example, the thicknesses of the piezoelectric layer portions 14-1 to 14-3 of the SAW device 56 are formed with a symmetric pattern. The embodiments illustrated in FIGS. 8C and 8D further demonstrate additional degrees of freedom within individual SAW devices that are provided by the ability to vary thicknesses of a piezoelectric layer. Such additional degrees of freedom may provide the ability to tailor different wave properties, such as velocity, coupling and frequency. Accordingly, effective coupling of a certain resonator may be tailored, e.g., smaller coupling for a shorter transition between fs and fp. For SAW devices that may be used within a filter topology, these principles may be used to provide a steeper transition of a resulting filter skirt. Suppression of energy leakage may also be provided in the propagation direction, the transverse direction, or into the layered substrate.

FIGS. 8E and 8F are a top-view illustration for SAW devices 58, 60 where the piezoelectric layer is formed with different thicknesses along a propagation direction and a transverse direction of the SAW devices 58, 60 according to principles of the present disclosure, thereby combining advantages of one or more of the tailored resonator properties as described above for FIGS. 8A to 8D. In FIG. 8F, the SAW device 60 demonstrates different piezoelectric layer thickness portions 14-1 to 14-5 that form a symmetric pattern about both the propagation direction and the transverse direction.

For any of the above-described embodiments for FIGS. 8A to 8F, thickness transitions between the piezoelectric layer portions (e.g., 14-1 to 14-9) may be arranged in any number of configurations. For example, the thickness transitions may comprise sloped or continuously graded thickness transitions that may promote formation of the electrode fingers 22 in a more continuous manner, thereby improving conductivity by reducing thinner or narrower sections that may otherwise form in the electrode fingers 22. In other embodiments, thickness transitions between the piezoelectric layer portions (e.g., 14-1 to 14-9) may be arranged in other configurations, for example single-step or multiple-step configurations for each thickness transition.

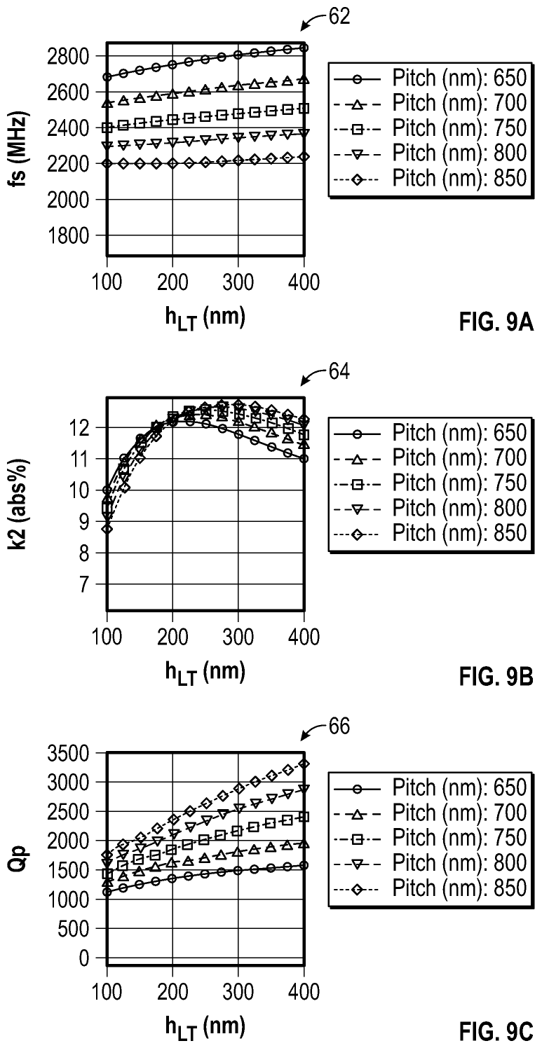

Embodiments of the present disclose may be applied for a variety of operating frequency bands in radio frequency (RF) applications. With a bandwidth of 194 MHz at a frequency around 2.55 gigahertz (GHz), an example of a challenging band is band 41 (B41). For B41, more than 10% coupling with high Q values may be needed to provide good filter performance. FIGS. 9A-9C provide results of finite element (FEM) simulations of an exemplary SAW resonator stack that is configured for B41 operation. For the purpose of the FEM simulations, the SAW resonator structures include an LT piezoelectric layer with variable thicknesses h_{LT} in a range from 100 nm-400 nm on an intermediate layer of SiO₂ with a thickness of 240 nm, and a silicon substrate. Additionally, the SAW resonators are implemented with IDT electrode fingers of varying IDT pitch, with duty factor (DF) of 50% and comprising an aluminum copper alloy with a thickness of 150 nm.

FIG. 9A is a plot 62 illustrating the resonance frequency fs and its dependence on LT piezoelectric layer thickness h_{LT} for the FEM simulations. FIG. 9B is a plot 64 illustrating the resulting coupling coefficient k2, and FIG. 9C is a plot 66 illustrating the resulting quality factor at anti-resonance Qp for the FEM simulations. As illustrated in FIGS. 9B and 9C, a trade-off between coupling and quality factor at anti-resonance Qp exists for each of the various IDT pitches. For LT piezoelectric layer thickness h_{LT}, higher quality factors at anti-resonance Qp are achievable while coupling k2 decreases. At the same time, for different IDT pitches, the largest coupling k2 value does not occur for the same LT thickness. In this regard, utilizing different LT piezoelectric layer thicknesses h_{LT} for devices on a same die, it becomes possible to choose a different working point for each resonator within the B41 filter. In this example, a high coupling k2 for some resonators (e.g., above 12% coupling in FIG. 9B) is provided, while larger quality factors at anti-resonance Qp for other resonators are provided on the same die. In practice, the actual optimization of acoustic parameter trade-offs may be multi-dimensional while accounting for additional device requirements. As disclosed herein, the freedom of choice in the piezoelectric layer thickness provides a new degree of freedom which is currently not available within conventional SAW filter design and optimization procedures.

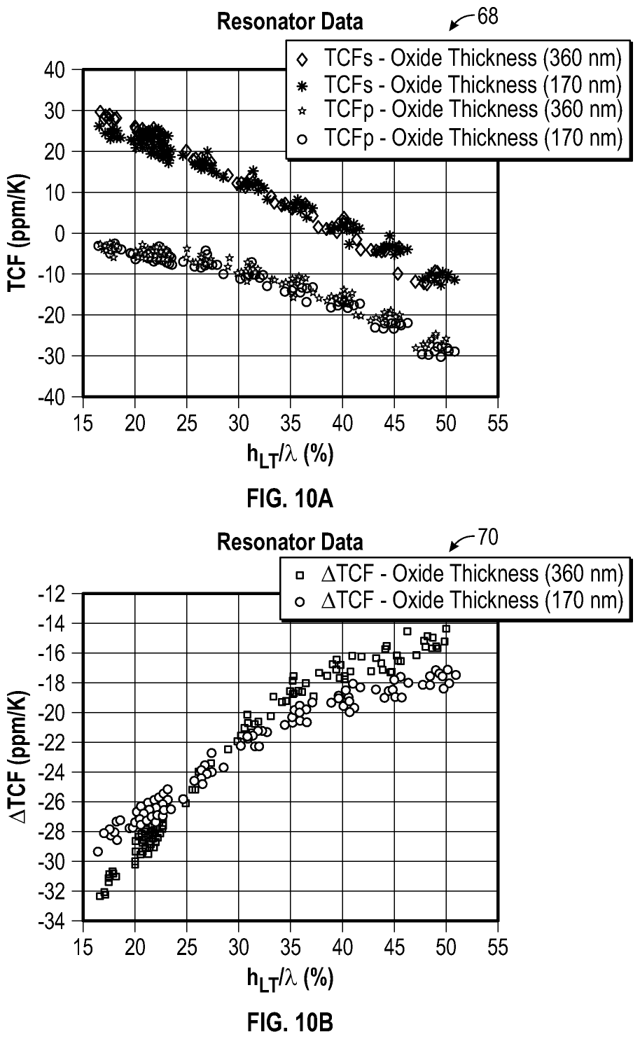

Another important acoustic resonator property for SAW devices that may be tuned with the piezoelectric layer thickness is the temperature coefficient of frequency (TCF). FIGS. 10A and 10B are plots that demonstrate measured TCF values of SAW resonators at resonance (TCFs), antiresonance (TCFp), and their difference (ΔTCF) based on different piezoelectric layer thickness values. In both of FIGS. 10A and 10B, measurements for SAW resonator devices are provided for two different thickness values (e.g., 170 nm and 360 nm) of an intermediate layer of SiO₂. FIG. 10A is a plot 68 illustrating TCFs and TCFp measurements across a range of LT piezoelectric layer thicknesses

$$( \frac{{h}_{LT}}{λ} )$$

for each of the SiO₂ thickness values. FIG. 10B is a plot 70 that illustrates the difference ΔTCF between the TCFs and TCFp values of FIG. 10A. By adjusting the LT piezoelectric layer thickness

$$( \frac{{h}_{LT}}{λ} )$$

for different resonators within a filter die, tailoring the thermal behavior of the filter die becomes more flexible. For example, certain resonators may be configured to have much smaller TCF values than others where TCFs is almost zero for

$$\frac{{h}_{LT}}{λ}$$

values close to 40%. TCFp on the other hand is close to zero for

$$\frac{{h}_{LT}}{λ}$$

values close to 15%. According to principles of the present disclosure, different

$$\frac{{h}_{LT}}{λ}$$

values and corresponding SAW resonator stacks with different TCF values may be combined within a single filter or within several filters on a monolithic chip. In the manner, new solutions may be enabled which are currently not achievable for conventional SAW resonators where TCF values for resonators at a certain frequency are fixed values which have to be accounted for within filter designs. The principles of the present disclosure may also be applicable to other filter characteristics, including variations over temperature of voltage standing wave ratio (VSWR), among others. In this regard, tailoring piezoelectric layer thicknesses according to the present disclosure may be implemented to better adjust temperature shifts of shunt and series resonators in the center of a passband in order to have a more stable response over a targeted temperature range.

SAW resonators are also known to exhibit spurious modes, such as Rayleigh modes below fs of the main mode, longitudinally polarized modes above fs, and higher order modes at even higher frequencies. Such out-of-band modes can fall into frequency ranges of other bands, creating challenges for multiplexing SAW filters within modules. This may become even more challenging with further increases in carrier aggregation requirements. As each mode has different sensitivities to the piezoelectric layer thickness, the principles of the present disclosure of tailoring the piezoelectric layer thickness for different SAW resonators within a filter structure may provide a new degree of freedom for suppressing the out-of-band modes of resonators within the filter or shifting them to frequencies which are more favorable for the application, such as a narrow frequency range between relevant bands.

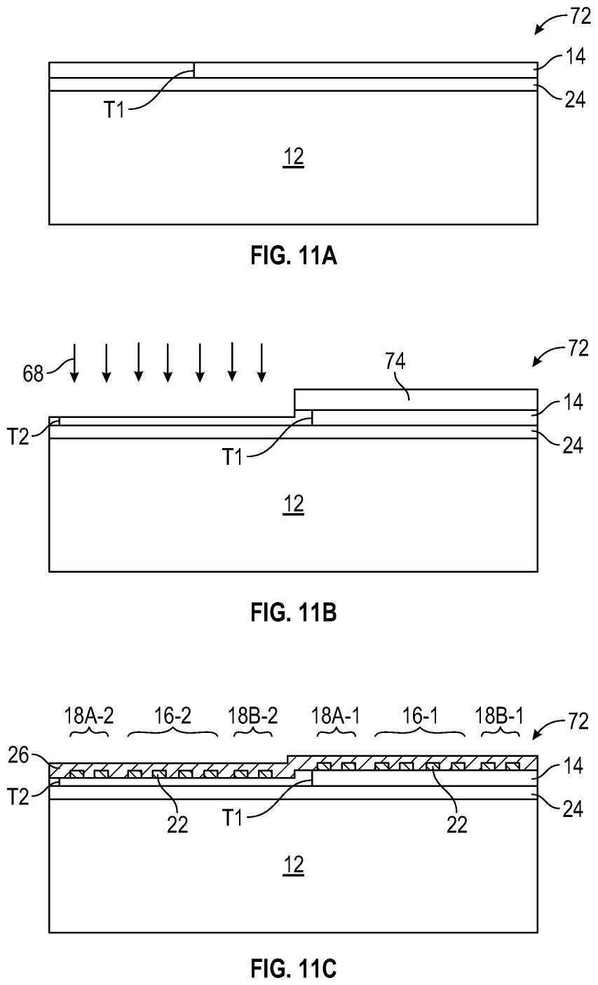

As previously described, tailoring or shaping piezoelectric layer thicknesses within SAW devices may involve selectively removing portions of the piezoelectric layer with selectively etching fabrication steps. By way of example, FIGS. 11A-11C are cross-section illustrations at various sequential fabrication steps that involve a patterned etch and/or a patterned trim procedure for a SAW device 72. In FIG. 11A, the SAW device 72 is provided with the piezoelectric layer 14 on the substrate 12 with the intermediate layer 24 therebetween as previously described. The piezoelectric layer 14 may be bonded to or otherwise formed on the substrate 12 and the intermediate layer 24. As illustrated, the piezoelectric layer 14 is formed with the first thickness T1 across the SAW device 72. In the fabrication step of FIG. 11B, an etch mask 74, such as a hard mask or a patterned resist, is selectively applied over portions of the piezoelectric layer 14. An ion beam plasma 75 may then be applied over the SAW device 72 to selectively remove portions of the piezoelectric layer 14 that are uncovered by the etch mask 74. In this manner, etched regions of the piezoelectric layer 14 are provided with the second thickness T2. While only a single step in the thickness profile for the piezoelectric layer 14 is illustrated, the fabrication step of selective removal may be repeated any number of times to provide many different piezoelectric layer thicknesses across the substrate 12. In the fabrication step of FIG. 11C, the etch mask 74 of FIG. 11B has been removed and various SAW structures may be formed by patterning IDTs 16-1 and 16-2 and corresponding reflector structures 18A-1, 18-1 and 18A-2, 18-2 on the piezoelectric layer 14. The dielectric layer 26 may then be formed over the SAW device 72. In this manner, a SAW structure formed by the IDT 16-2 and corresponding reflector structures 18A-2 and 18-2 is provided on an etched surface of the piezoelectric layer 14. In further embodiments, additional etch masks like the etch mask 74 of FIG. 11B may be provided over each electrode finger 22 of at least one of the patterned IDTs 16-1, 16-2 before application of the dielectric layer 26. For such embodiments, selective removal of portions of the piezoelectric layer 14 that are registered between adjacent pairs of the electrode fingers 22 may then be performed to provide a structure similar to the SAW device 48 of FIG. 7.

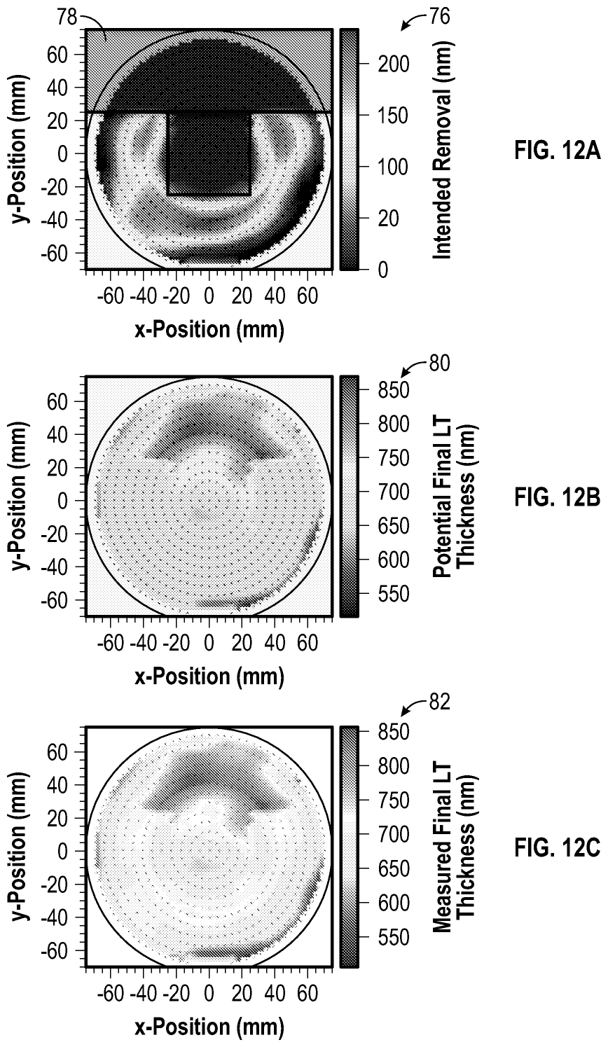

In order to evaluate the relative quality of SAW structures formed on etched surfaces of piezoelectric layers, a large area layered substrate structure for a bonded wafer was provided that included an LT piezoelectric layer on an intermediate layer of SiO₂. For such large area wafers, thickness variations in the overall wafer may be present. In this regard, the piezoelectric layer wafer was subjected to selective etching such that certain etched regions may have similar thicknesses with other areas of the wafer that were not etched. Corresponding SAW resonators with the same LT piezoelectric layer thickness (and SiO₂ thickness) where then chosen for quality factor comparisons. FIG. 12A is an illustration of a removal map 76 that indicates differences in thickness across a wafer. An etch mask 78 was patterned over the wafer and portions of the wafer that were uncovered by the etch mask 78 were subjected to ion plasma etching. FIG. 12B is an illustration of a potential or theoretical post-etch map 80 for an idealized etching process, and FIG. 12C is a measured post-etch map 82 for the wafer. Some differences between the measured post-etch map 82 and the theoretical post-etch map 80 are expected as a finite ion beam size may lead to non-trimmable short distance thickness differences. Other factors that may lead to differences may be variations or fluctuations in etch rates, as well as finite precision of the thickness measurement tool. Thinning of the piezoelectric layer was performed for amounts of up to 230 nm or about 30% of the overall piezoelectric layer thickness.

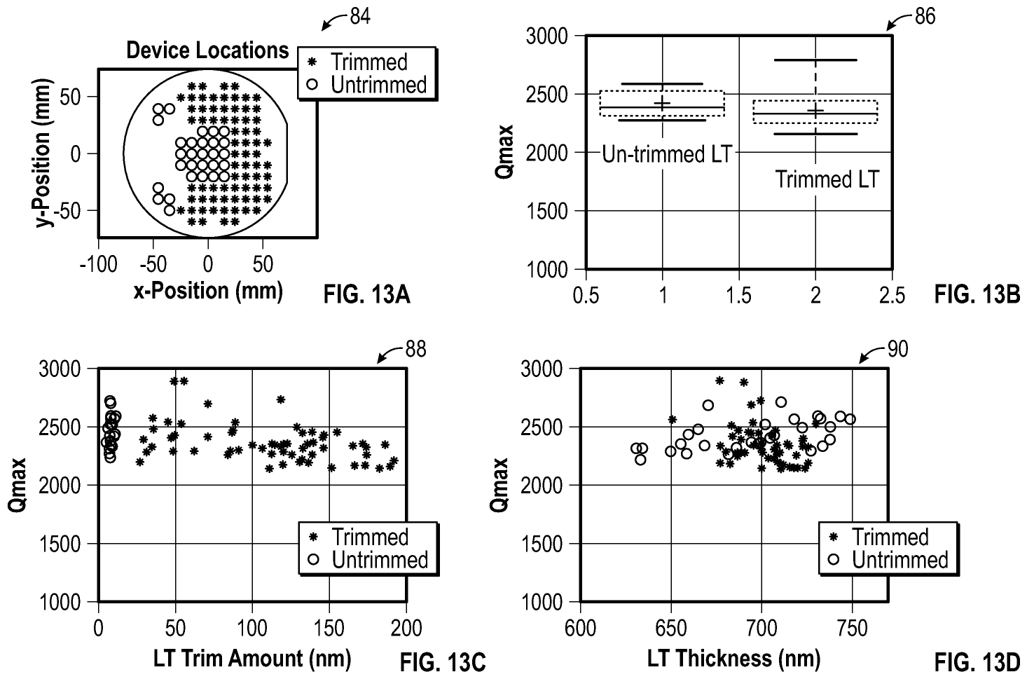

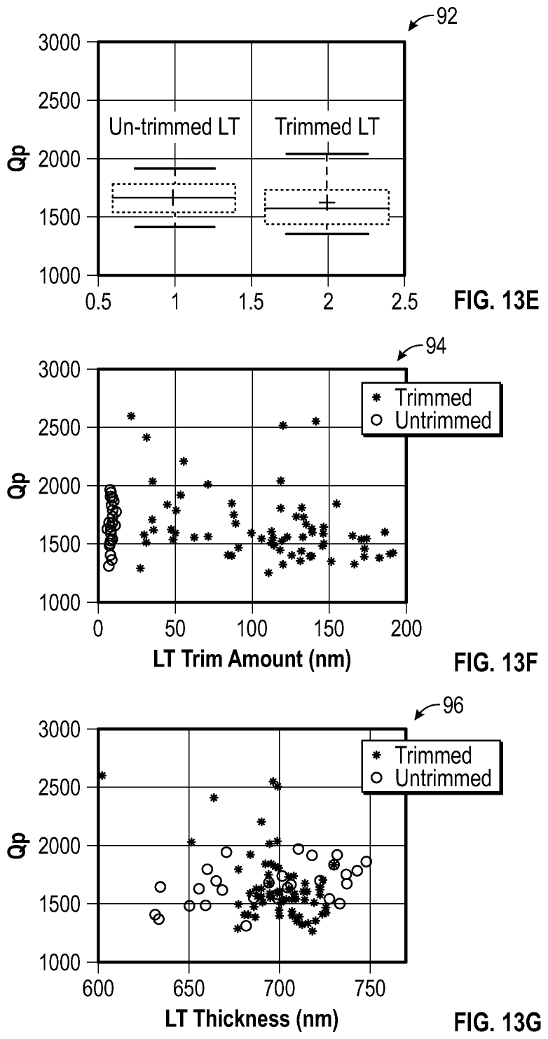

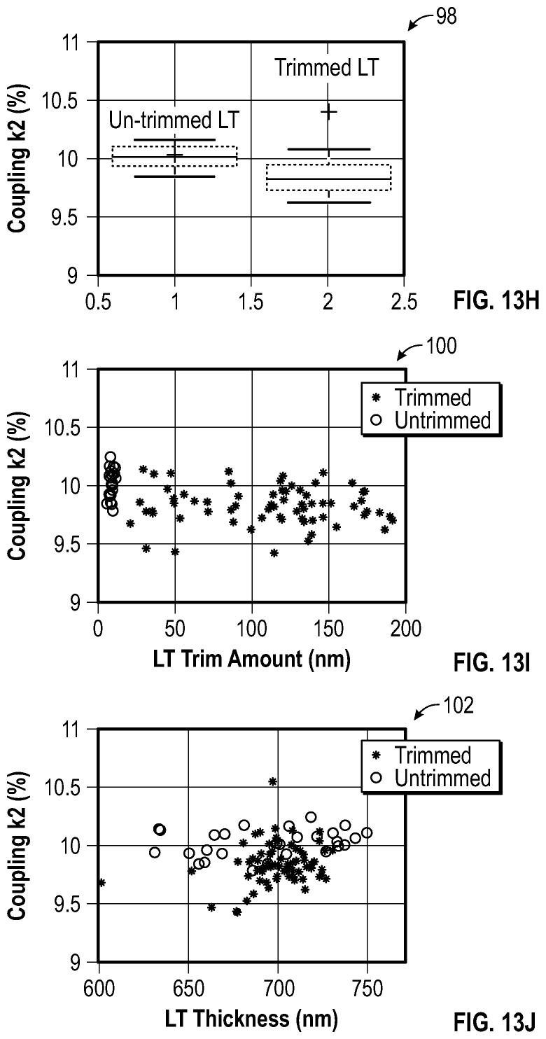

FIGS. 13A-13J are plots illustrating a comparison of the quality factor and coupling of the SAW resonators fabricated after the selective removal step characterized in the maps of FIGS. 12A-12C. SAW resonators were chosen at etched and unetched (or trimmed and untrimmed) wafer locations that had comparable thin film thicknesses for the SiO₂ layer and the piezoelectric layer. For the purposes of the comparison, SiO₂ layer and the piezoelectric layer thicknesses were filtered within limits to provide a suitable comparison, and quality factors (Q_{MAX} in FIGS. 13B to 13D, QOp in FIGS. 13E to 13G) and coupling (k2 in FIGS. 13H to 13J) were extracted for resonators with a resonance frequency of about 1 GHz. FIG. 13A is a wafer map 84 that indicates relative wafer locations for the trimmed and untrimmed resonator device locations chosen for measurements. FIG. 13B is a graph 86 that indicates that the resonators from trimmed and untrimmed wafer areas show comparable quality factors of about 2400 at 1 GHz. FIG. 13C is a graph 88 that indicates no significant decrease of the quality factor based on the amount of piezoelectric layer removed (LT trim amount). Finally, FIG. 13D is a graph 90 that indicates the piezoelectric layer thickness (LT thickness) variation between the filtered devices is comparable between the trimmed and untrimmed wafer areas. FIG. 13E is a graph 92 that indicates that the resonators from trimmed and untrimmed wafer areas show comparable antiresonance quality factors Qp at 1 GHz. FIG. 13F is a graph 94 that indicates no significant decrease of the antiresonance quality factor based on the amount of piezoelectric layer removed (LT trim amount). FIG. 13G is a graph 96 that indicates the piezoelectric layer thickness (LT thickness) variation between the filtered devices is comparable between the trimmed and untrimmed wafer areas. FIG. 13H is a graph 98 that indicates that the resonators from trimmed and untrimmed wafer areas show comparable coupling at 1 GHz. FIG. 13I is a graph 100 that indicates no significant decrease of the antiresonance quality factor based on the amount of piezoelectric layer removed (LT trim amount). Finally, FIG. 13J is a graph 102 that indicates the piezoelectric layer thickness (LT thickness) variation between the filtered devices is comparable between the trimmed and untrimmed wafer areas. In this regard, selective removal of piezoelectric material in certain areas, including more than 200 nm, may be achieved with no observable impact on the performance of the resulting devices. As such, guided SAW resonators may be fabricated on trimmed or etched areas of a piezoelectric layer with no observable quality factor and coupling differences to comparable guided SAW resonators fabricated on non-trimmed areas.

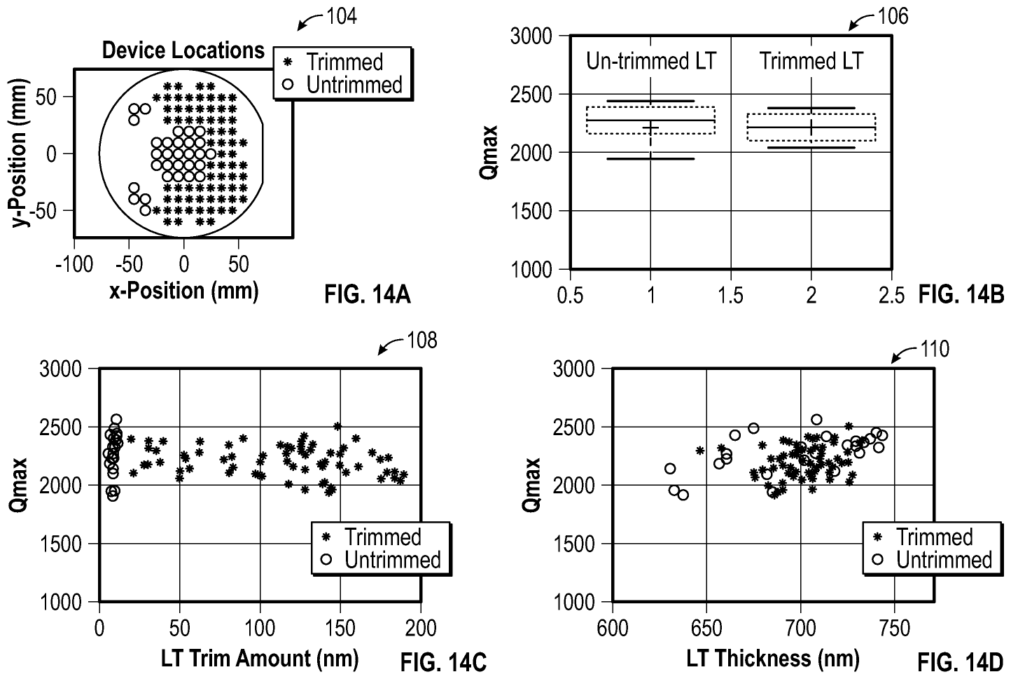

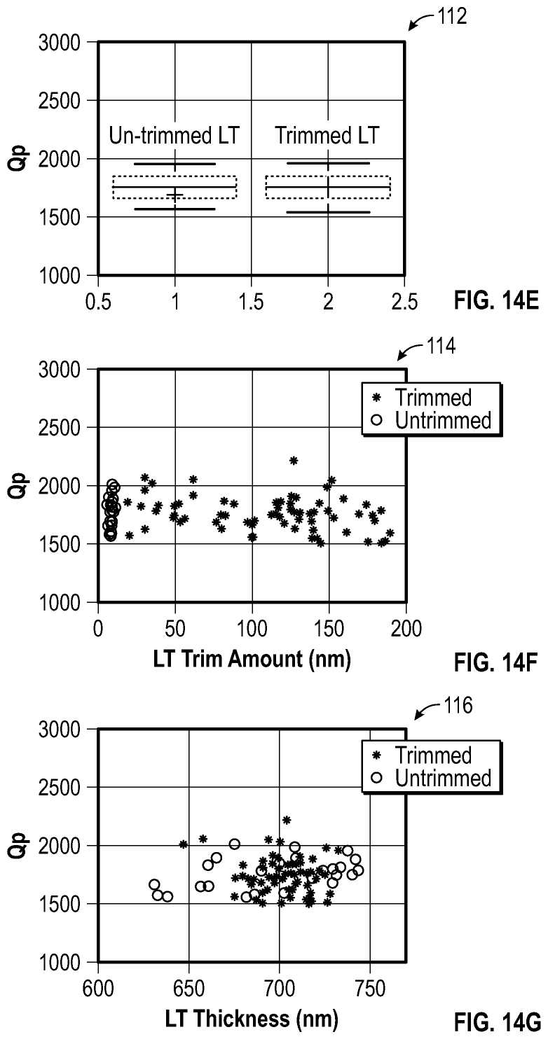

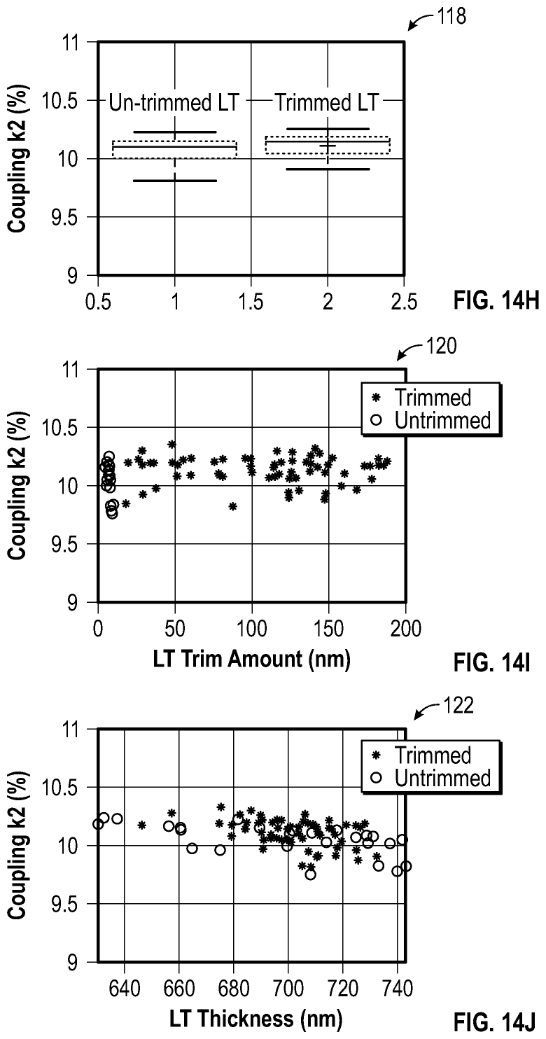

In order to evaluate the relative quality of SAW structures formed on etched surfaces of piezoelectric layers for higher band applications, a layered substrate structure was provided and selectively etched in a similar manner as described above for FIGS. 12A-12C. Corresponding SAW resonators with the same LT piezoelectric layer thickness (and SiO₂ thickness) where then chosen for quality factor comparisons. FIGS. 14A-14J are plots illustrating a comparison of the quality factor and coupling of the SAW resonators fabricated after the selective removal steps. SAW resonators were chosen at etched and unetched (or trimmed and untrimmed) wafer locations that had comparable thin film thicknesses for the SiO₂ layer and the piezoelectric layer. For the purposes of the comparison, SiO₂ layer and the piezoelectric layer thicknesses were filtered within limits to provide a suitable comparison, and quality factors (Q_{MAX} in FIGS. 14B to 14D, Qp in FIGS. 14E to 14G) and coupling (k2 in FIGS. 14H to 14J) were extracted for resonators with a resonance frequency of about 1.7 GHz. FIG. 14A is a wafer map 104 that indicates relative wafer locations for the trimmed and untrimmed resonator device locations chosen for measurements. FIG. 14B is a graph 106 that indicates the resonators from trimmed and untrimmed wafer areas show comparable quality factors at about 2200 at 1.7 GHz. FIG. 14C is a graph 108 that indicates no significant decrease of the quality factor based on the amount of piezoelectric layer removed (LT trim amount). Finally, FIG. 14D is a graph 110 that indicates the piezoelectric layer thickness (LT thickness) variation between the filtered devices is comparable between the trimmed and untrimmed wafer areas. FIG. 14E is a graph 112 that indicates that the resonators from trimmed and untrimmed wafer areas show comparable antiresonance quality factors Qp at 1.7 GHz. FIG. 14F is a graph 114 that indicates no significant decrease of the antiresonance quality factor based on the amount of piezoelectric layer removed (LT trim amount). FIG. 14G is a graph 116 that indicates the piezoelectric layer thickness (LT thickness) variation between the filtered devices is comparable between the trimmed and untrimmed wafer areas. FIG. 14H is a graph 118 that indicates that the resonators from trimmed and untrimmed wafer areas show comparable coupling at 1.7 GHz. FIG. 14I is a graph 120 that indicates no significant decrease of the antiresonance quality factor based on the amount of piezoelectric layer removed (LT trim amount). Finally, FIG. 14J is a graph 122 that indicates the piezoelectric layer thickness (LT thickness) variation between the filtered devices is comparable between the trimmed and untrimmed wafer areas. In this regard, selective removal of piezoelectric material may be provided for low band applications, such as in a range from about 600-1000 MHz as illustrated in FIGS. 13A-13J, as well as mid-high-band applications above 1.4 GHz as illustrated in FIGS. 14A-14J with no observable quality impact in the resulting devices. As such, guided SAW resonators may be fabricated on trimmed or etched areas of a piezoelectric layer with no observable quality factor and coupling differences to comparable guided SAW resonators fabricated on non-trimmed areas across a variety of frequency bands.

The principles of the present disclosure may be applicable to all acoustic resonators, including the guided SAW devices disclosed above. Different piezoelectric thin film thicknesses across layered substrates of such devices may enable a degree of freedom which is otherwise not accessible. Advantageous effects include the ability to provide improved and tailored performance characteristics by providing different piezoelectric film thicknesses for sets of resonators formed on a common substrate, and different piezoelectric film thicknesses in filters within a monolithic die, including improved monolithic two-in-one duplexers, four-in-one quadplexers, or larger order multiplexers and other combinations of filters.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A surface acoustic wave (SAW) device, comprising:
a carrier substrate;
a piezoelectric layer on the carrier substrate, wherein a first portion of the piezoelectric layer has a first thickness as measured in a direction perpendicular to the carrier substrate, a second portion of the piezoelectric layer has a second thickness as measured in the direction perpendicular to the carrier substrate, and wherein the first thickness is different than the second thickness; and
at least one electrode on a surface of the piezoelectric layer opposite the carrier substrate.

2. The SAW device of claim 1, wherein the at least one electrode comprises a plurality of electrodes on the piezoelectric layer that define a first SAW filter structure and a second SAW filter structure on the carrier substrate, and the first SAW filter structure comprises the first portion of the piezoelectric layer and the second SAW filter structure comprises the second portion of the piezoelectric layer.

3. The SAW device of claim 2, wherein the first SAW filter structure and the second SAW filter structure each comprise a number of SAW resonators.

4. The SAW device of claim 3, wherein the first SAW filter structure and the second SAW filter structure further comprise a number of SAW coupled resonator filters.

5. The SAW device of claim 1, wherein the at least one electrode comprises a plurality of electrodes on the piezoelectric layer that define a SAW filter structure, and the SAW filter structure comprises a plurality of SAW resonators.

6. The SAW device of claim 5, wherein the plurality of SAW resonators form a number of series resonators that comprise the first portion of the piezoelectric layer and a number of shunt resonators that comprise the second portion of the piezoelectric layer.

7. The SAW device of claim 1, wherein the at least one electrode comprises an interdigitated transducer (IDT) and the SAW device further comprises first and second reflective structures that are arranged on the piezoelectric layer such that the IDT is positioned between the first reflective structure and the second reflective structure.

8. The SAW device of claim 7, wherein the IDT is arranged on the first portion of the piezoelectric layer and the first and second reflective structures are arranged on the second portion of the piezoelectric layer.

9. The SAW device of claim 7, wherein the first portion of the piezoelectric layer is registered with individual electrode fingers of the IDT and the second portion of the piezoelectric layer is registered between adjacent pairs of the individual electrode fingers.

10. The SAW device of claim 7, wherein the first portion of the piezoelectric layer and the second portion of the piezoelectric layer are arranged along a transverse direction of the SAW device such that an electrode finger of the IDT is arranged on both the first portion of the piezoelectric layer and the second portion of the piezoelectric layer.

11. The SAW device of claim 10, wherein a third portion of the piezoelectric layer comprises a third thickness as measured in the direction perpendicular to the carrier substrate, wherein the third thickness is different that the first thickness and the second thickness, and the electrode finger is arranged on the first, second, and third portions of the piezoelectric layer.

12. A method comprising:
providing a carrier substrate;
providing a piezoelectric layer on the carrier substrate;
shaping the piezoelectric layer such that a first portion of the piezoelectric layer is formed with a first thickness as measured in a direction perpendicular to the carrier substrate, a second portion of the piezoelectric layer is formed with a second thickness as measured in the direction perpendicular to the carrier substrate, and wherein the first thickness is different than the second thickness; and
providing at least one electrode on a surface of the piezoelectric layer opposite the carrier substrate.

13. The method of claim 12, wherein shaping the piezoelectric layer comprises applying a selective removal process to form the second portion of the piezoelectric layer such that the second thickness is less than the first thickness.

14. The method of claim 13, wherein the selective removal process comprises forming a patterned etch mask over the first portion of the piezoelectric layer and selectively etching the second portion of piezoelectric layer.

15. The method of claim 13, wherein the at least one electrode is formed on the second portion of the piezoelectric layer.

16. The method of claim 12, wherein the at least one electrode comprises a plurality of electrodes on the piezoelectric layer that define a first surface acoustic wave (SAW) filter structure and a second SAW filter structure on the carrier substrate, and the first SAW filter structure comprises the first portion of the piezoelectric layer and the second SAW filter structure comprises the second portion of the piezoelectric layer.

17. The method of claim 16, wherein the first SAW filter structure and the second SAW filter structure each comprise a number of SAW resonators.

18. The method of claim 12, wherein the at least one electrode comprises a plurality of electrodes on the piezoelectric layer that define a surface acoustic wave (SAW) filter structure, and the SAW filter structure comprises a plurality of SAW resonators.

19. The method of claim 18, wherein the plurality of SAW resonators form a number of series resonators that comprise the first portion of the piezoelectric layer and a number of shunt resonators that comprise the second portion of the piezoelectric layer.

20. The method of claim 12, wherein the at least one electrode comprises an interdigitated transducer (IDT) and the method further comprises providing first and second reflective structures that are arranged on the piezoelectric layer such that the IDT is positioned between the first reflective structure and the second reflective structure.

21. The method of claim 20, wherein the IDT is arranged on the first portion of the piezoelectric layer and the first and second reflective structures are arranged on the second portion of the piezoelectric layer.

22. The method of claim 20, wherein the first portion of the piezoelectric layer and the second portion of the piezoelectric layer are arranged along a transverse direction of the piezoelectric layer such that an electrode finger of the IDT is arranged on both the first portion of the piezoelectric layer and the second portion of the piezoelectric layer.
